(19) United States
(12) Patent Application Publication
(10) Pub. No.: US 2018/0277052 A1
(43) Pub. Date: Sep. 27, 2018

(54) SHIFT REGISTER UNIT, DRIVING METHOD AND GATE DRIVING CIRCUIT

(71) Applicants: BOE TECHNOLOGY GROUP CO., LTD., Beijing (CN); BEIJING BOE DISPLAY TECHNOLOGY CO., LTD., Beijing (CN)

(72) Inventors: Yingmeng MIAO, Beijing (CN); Yujie GAO, Beijing (CN)

(21) Appl. No.: 15/763,544

(22) PCT Filed: Jul. 20, 2017
(86) PCT No.: PCT/CN2017/093629

§ 371 Date: Mar. 27, 2018

(30) Foreign Application Priority Data
Aug. 17, 2016 (CN) 201610681864.3

(51) Int. Cl. G09G 3/36; G11C 19/28

(52) U.S. Cl. CPC G09G 3/3677; G11C 19/28; G09G 2310/061; G09G 2310/0283; G09G 2310/0286

(57) ABSTRACT

A shift register unit, a driving method, and a gate driving circuit are disclosed. The shift register unit includes an input reset sub-circuit, which is connected to a first scan control terminal, a second scan control terminal, a first scan level terminal, a second scan level terminal and a pull-up node, respectively, and configured to control the pull-up node to connect with the first scan level terminal or the second scan level terminal under the control of a first scan control signal fed through the first scan control terminal and a second scan control signal fed through the second scan control terminal; a gate driving signal output sub-circuit; and a gate driving signal reset sub-circuit.

### RELATED APPLICATION

The present application is the U.S. national phase entry of PCT/CN2017/093629, with an international filing date of Jul. 20, 2017, which claims the benefit of Chinese Patent Application No. 201610681864.3, filed on Aug. 17, 2016, the entire disclosure of which is incorporated herein by reference.

### FIELD

The present disclosure relates to the field of display driving technology, and particularly to a shift register unit, a driving method and a gate driving circuit.

### BACKGROUND

As the number of customers of TV (television) products continues to increase, different customers have different requirements on the scanning manner of a liquid crystal panel. Specifically, some customers want to put the panel right-side up to be scanned from the first row, and others want to put the panel upside down to be scanned from the last row. In order to match the customer organization design and meet the customer requirements, the concept of bidirectional scanning is also gradually introduced to TV products. The so-called bidirectional scanning means that the liquid crystal display panel may be scanned from the first row and may also be scanned from the last row. In this way, an erect image can be eventually displayed regardless of whether the customers put the liquid crystal display panel right-side up or upside down to match the whole machine.

The row driving scanning for the existing liquid crystal display panel is Chip On Film (COF) driving, and the COF chips of the integrated circuit (IC) manufactures mostly provide the function of bidirectional scanning. In order to reduce the cost of an existing TV product, Gate driving basically adopts a Gate On Array (GOA) design. However, the current TV GOA driving does not realize bidirectional scanning.

### SUMMARY

The main object of the present disclosure is to provide a shift register unit, a driving method and a gate driving circuit.

In order to achieve the above object, embodiments of the present disclosure provide a shift register unit, comprising:

an input reset sub-circuit, which is connected to a first scan control terminal, a second scan control terminal, a first scan level terminal, a second scan level terminal and a pull-up node, respectively, and configured to control the pull-up node to connect with one of the first scan level terminal and the second scan level terminal under the control of a first scan control signal fed through the first scan control terminal and a second scan control signal fed through the second scan control terminal;

a gate driving signal output sub-circuit, which is connected to the pull-up node, a gate driving signal output terminal and a first clock signal terminal, respectively, and configured to control the gate driving signal output terminal to connect with the first clock signal terminal in response to a potential of the pull-up node being a first gating potential; and,

a gate driving signal reset sub-circuit, which is connected to a reset control terminal, the gate driving signal output terminal and a first level terminal, respectively, and configured to control the gate driving signal output terminal to connect with the first level terminal under the control of a reset control signal loaded through the reset control terminal,

wherein during forward scanning, the first scan control terminal acts as an input terminal and the second scan control terminal acts as a reset terminal; during reverse scanning, the first scan control terminal acts as the reset terminal and the second scan control terminal acts as the input terminal.

In an exemplary embodiment, the shift register unit of the present disclosure further comprises a first pull-down control sub-circuit, which is connected to the pull-up node, a pull-down node and the first level terminal, respectively, and configured to control the pull-up node to connect with the first level terminal in response to a potential of the pull-down node being a second level;

a pull-down node control sub-circuit, which is connected to the pull-up node, the pull-down node, a second level terminal and the first level terminal, respectively, and configured to control the pull-down node to connect with the first level terminal in response to the potential of the pull-up node being a second gating potential, and control the pull-down node to connect with the second level terminal in response to the potential of the pull-up node being a first level; and

a second pull-down control sub-circuit, which is connected to the pull-down node, the gate driving signal output terminal and the first level terminal, respectively, and controls the gate driving signal output terminal to connect with the first level terminal in response to the potential of the pull-down node being the second level.

In an exemplary embodiment, the input reset sub-circuit comprises a first input reset transistor and a second input reset transistor;

a gate of the first input reset transistor is connected to the first scan control terminal, a first terminal of the first input reset transistor is connected to the first scan level terminal, and the second terminal of the first input reset transistor is connected to the pull-up node;

a gate of the second input reset transistor is connected to the second scan control terminal, a first terminal of the second input reset transistor is connected to the pull-up node, and a second terminal of the second input reset transistor is connected to the second scan level terminal.

In an exemplary embodiment, the gate driving signal output sub-circuit comprises:

a gate driving signal output transistor, wherein a gate of the gate driving signal output transistor is connected to the pull-up node, a first terminal of the gate driving signal output transistor is connected to the first clock signal terminal, and a second terminal of the gate driving signal output transistor is connected to the gate driving signal output terminal; and

a storage capacitor, wherein a first terminal of the storage capacitor is connected to the pull-up node, and a second terminal of the storage capacitor is connected to the gate driving signal output terminal.

In an exemplary embodiment, the gate driving signal reset sub-circuit comprises a gate driving signal reset transistor, wherein

a gate of the gate driving signal reset transistor acts as the reset control terminal;

the gate of the gate driving signal reset transistor is connected to a second clock signal terminal, a first terminal of the gate driving signal reset transistor is connected to the gate driving signal output terminal, and a second terminal of the gate driving signal reset transistor is connected to the first level terminal; and

the first clock signal and a second clock signal fed through the second clock signal terminal are opposite in phase.

In an exemplary embodiment, the pull-down node control sub-circuit comprises:

a first pull-down node control transistor, wherein a gate of the first pull-down node control transistor is connected to the pull-up node, a first terminal of the first pull-down node control transistor is connected to the pull-down node, and a second terminal of the first pull-down node control transistor is connected to the first level terminal;

a second pull-down node control transistor, wherein a gate and a first terminal of the second pull-down node control transistor are both connected to a second level terminal,

a third pull-down node control transistor, wherein a gate of the third pull-down node control transistor is connected to a second terminal of the second pull-down node control transistor, a first terminal of the third pull-down node control transistor is connected to the second level terminal, and a second terminal of the third pull-down node control transistor is connected to the pull-down node; and

a fourth pull-down node control transistor, wherein a gate of the fourth pull-down node control transistor is connected to the pull-up node, a first terminal of the fourth pull-down node control transistor is connected to the second terminal of the second pull-down node control transistor, and a second terminal of the fourth pull-down node control transistor is connected to the first level terminal.

In an exemplary embodiment, the first pull-down sub-circuit comprises a first pull-down control transistor, wherein a gate of the first pull-down control transistor is connected to the pull-down node, a first terminal of the first pull-down control transistor is connected to the pull-up node, and a second terminal of the first pull-down control transistor is connected to the first level terminal;

the second pull-down control sub-circuit comprises a second pull-down control transistor, wherein a gate of the second pull-down control transistor is connected to the pull-down node, a first terminal of the second pull-down control transistor is connected to the gate driving signal output terminal, and a second terminal of the second pull-down control transistor is connected to the first level terminal.

The present disclosure further provides a driving method of a shift register unit for driving the shift register unit described above. The driving method comprises:

in an input phase, the input reset sub-circuit controlling the potential of the pull-up node to be a second level, the first clock signal terminal being fed with a first level, the reset control terminal being fed with the second level, both the gate driving signal output sub-circuit and the gate driving signal reset sub-circuit controlling the gate driving signal output terminal to output the first level;

in an output phase, the first clock signal terminal being fed with the second level, the reset control terminal being fed with the first level, the gate driving signal output sub-circuit controlling to pull up the potential of the pull-up node by bootstrap and controlling the gate driving signal output terminal to output the second level;

in a reset phase, a potential of an input signal being the first level, a potential of a reset signal being the second level, the input reset sub-circuit controlling the potential of the pull-up node to be the first level, the first clock signal terminal being fed with the first level, the reset control terminal being fed with the second level, the gate driving signal reset sub-circuit controlling the gate driving signal output terminal to output the first level.

In an exemplary embodiment, during forward scanning,

the step of in an input phase, the input reset sub-circuit controlling the potential of the pull-up node to be the second level comprises: in the input phase, a potential of an input signal fed through the first scan control terminal being the second level, a potential of a reset signal fed through the second scan control terminal being the first level, the first scan level terminal being fed with the second level, the input reset sub-circuit is controlling the pull-up node to connect with the first scan level terminal so as to control the potential of the pull-up node to be the second level;

the step of in a reset phase, the input reset sub-circuit controlling the potential of the pull-up node to be the first level comprises: in the reset phase, the potential of the input signal being the first level, the potential of the reset signal being the second level, the second scan level terminal being fed with the first level, the input reset sub-circuit controlling the pull-up node to connect with the second scan level terminal so as to control the potential of the pull-up node to be the first level.

In an exemplary embodiment, during reverse scanning,

the step of in an input phase, the input reset sub-circuit controlling the potential of the pull-up node to be the second level comprises: in the input phase, a potential of an input signal fed through the second scan control terminal being the second level, a potential of a reset signal fed through the first scan control terminal being the first level, the second scan level terminal being fed with the second level, the input reset sub-circuit controlling the pull-up node to connect with the second scan level terminal so as to control the potential of the pull-up node to be the second level;

the step of in a reset phase, a potential of an input signal being the first level, a potential of a reset signal being the second level, the input reset sub-circuit controlling the potential of the pull-up node to be the first level comprise: in the reset phase, the potential of the input signal being the first level, the potential of the reset signal being the second level, the first scan level terminal being fed with the first level, the input reset sub-circuit controlling the pull-up node to connect with the first scan level terminal so as to control the potential of the pull-up node to be the first level.

In an exemplary embodiment, after the reset phase, the driving method further comprises:

an output cutoff holding phase, in which the reset control terminal is fed with the second level every other clock cycle, and in response to the reset control terminal outputting the second level, the gate driving signal reset sub-circuit controls the gate driving signal output terminal to output the first level.

In an exemplary embodiment, when the shift register unit comprises a first pull-down control sub-circuit, a pull-down node control sub-circuit and a second pull-down control sub-circuit, the driving method further comprises:

in the input phase and the output phase, the pull-down node control sub-circuit controlling the potential of the pull-down node to be the first level;

in the reset phase and the output cutoff holding phase, the pull-down node control sub-circuit controlling the potential of the pull-down node to be the second level, the first pull-down control sub-circuit controlling the potential of the pull-up node to be the first level, the second pull-down control sub-circuit controlling the gate driving signal output terminal to output the first level.

The present disclosure further provides a gate driving circuit comprising multiple rows of the shift register units described above, wherein

a first scan control terminal of a shift register unit of each row except a shift register unit of the first row is connected to a gate driving signal output terminal of a shift register unit of an adjacent previous row, and a second scan control terminal of a shift register unit of each row except a shift register unit of the last row is connected to a gate driving signal output terminal of a shift register unit of an adjacent next row.

### BRIEF DESCRIPTION OF DRAWINGS

FIG. 1 is a structural diagram of a shift register unit provided by an embodiment of the present disclosure;

FIG. 2 is a structural diagram of a shift register unit provided by another embodiment of the present disclosure;

FIG. 3 is a structural diagram of a shift register unit provided by a further embodiment of the present disclosure;

FIG. 4 is a circuit diagram of a specific embodiment of a shift register unit provided by an embodiment of the present disclosure;

FIG. 5 is an operational timing diagram of the specific embodiment of a shift register unit provided by an embodiment of the present disclosure as shown in FIG. 4;

FIG. 6 is a flow chart illustrating a driving method of a shift register unit provided by an embodiment of the present disclosure;

FIG. 7 is a structural and signal schematic diagram of a gate driving circuit provided by an embodiment of the present disclosure during forward scanning;

FIG. 8 is a structural and signal schematic diagram of a gate driving circuit provided by an embodiment of the present disclosure during reverse scanning; and

FIG. 9 is an operational timing diagram of a gate driving circuit provided by an embodiment of the present disclosure.

### DETAILED DESCRIPTION

The technical solutions in the embodiments of the present disclosure will be described below in a clear and complete manner with reference to the accompanying drawings in the embodiments of the present disclosure. Obviously, the described embodiments are merely a part but not all of the embodiments of the present disclosure. All other embodiments obtained by those ordinarily skilled in the art based on the embodiments of the present disclosure without spending inventive efforts fall within the protection scope of the present disclosure.

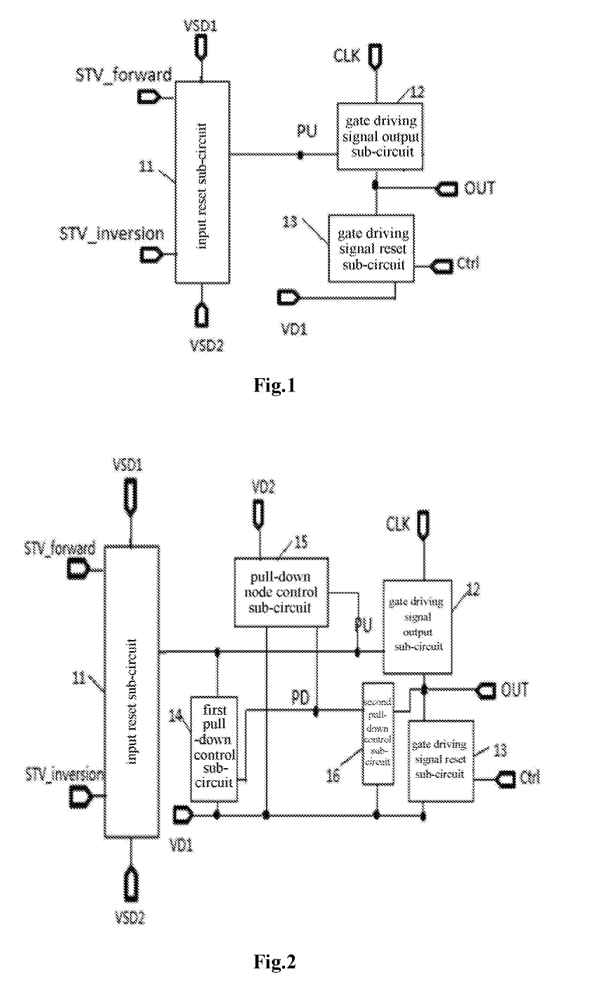

As shown in FIG. 1, a shift register unit provided by embodiments of the present disclosure comprises:

an input reset sub-circuit 11, which is connected to a first scan control terminal STV_forward, a second scan control terminal STV_inversion, a first scan level terminal VSD1, a second scan level terminal VSD2 and a pull-up node PU, respectively, and configured to control the pull-up node PU to connect with the first scan level terminal VSD1 or the second scan level terminal VSD2 under the control of a first scan control signal supplied from the first scan control terminal STV_forward and a second scan control signal supplied from the second scan control terminal STV_inversion;

a gate driving signal output sub-circuit 12, which is connected to the pull-up node PU, a gate driving signal output terminal OUT and a first clock signal terminal CLK, respectively, and configured to control the gate driving signal output terminal OUT to connect with the first clock signal terminal CLK when the potential of the pull-up node PU is a first gating potential; and

a gate driving signal reset sub-circuit 13, which is connected to a reset control terminal Ctrl, the gate driving signal output terminal OUT and a first level terminal VD1, respectively, and configured to control the gate driving signal output terminal OUT to connect with the first level terminal VD1 under the control of a reset control signal loaded from the reset control terminal Ctrl.

During forward scanning, the first scan control terminal STV_forward is an input terminal and the second scan control terminal STV_inversion is a reset terminal. During reverse scanning, the first scan control terminal STV_forward is a reset terminal and the second scan control terminal STV_forward is an input terminal.

In actual operation, the first gating potential is a potential capable of turning on a gate driving signal output transistor included in the gate driving signal output sub-circuit 12.

The connection manners for the first scan control terminal and the second scan control terminal in the input reset sub-circuit in the shift register unit provided by embodiments of the present disclosure are completely symmetrical. During forward scanning, the first scan control terminal is an input terminal and the second scan control terminal is an output terminal. During reverse scanning, the first scan control terminal is a reset terminal and the second scan control terminal is an input terminal. As a result, the shift register unit provided by embodiments of the present disclosure can conveniently realize bidirectional scanning in the GOA driving of a TV (television) product.

In actual operation, during forward scanning, the first scan level terminal VSD1 inputs a high level, and the second scan level terminal VSD2 inputs a low level. During reverse scanning, the first scan level terminal VSD1 inputs a low level, and the second scan level terminal VSD2 inputs a high level. That is, during forward and reverse scanning, the level inputted by the first scan level terminal VSD1 and the level inputted by the second scan level terminal VSD2 are alternately high and low so as to achieve forward and reverse scanning.

In actual operation, the first level terminal VD1 may be a low level input terminal. However, the first level terminal VD1 may also input other levels according to the actual situation, which is not limited here.

In an exemplary embodiment, as shown in FIG. 2, the shift register unit provided by embodiments of the present disclosure further comprises: a first pull-down sub-circuit 14, which is connected to the pull-up node PU, the pull-down node PD and the first level terminal VD1, respectively, and configured to control the pull-up node PU to connect with the first level terminal VD1 when the potential of the pull-down node PD is the second level;

a pull-down node control sub-circuit 15, which is connected to the pull-up node PU, the pull-down node PD, the second level terminal VD2 and the first level terminal VD1, respectively, and configured to control the pull-down node PD to connect with the first level terminal VD1 when the potential of the pull-up node PU is a second gating potential, and control the pull-down node PD to connect with the second level terminal VD2 when the potential of the pull-up node PU is the first level; and

a second pull-down control sub-circuit 16, which is connected to the pull-down node PD, the gate driving signal output terminal OUT and the first level terminal VD1, respectively, and controls the gate driving signal output terminal OUT to connect with the first level terminal VD1 when the potential of the pull-down node PD is the second level.

In actual operation, the second gating potential is a potential capable of turning on a pull-down node control transistor (i.e. M151 in FIG. 4) included in the pull-down node control sub-circuit 15, wherein a gate of the pull-down node control transistor is connected to the pull-up node to control the potential of the pull-down node to be the first level.

In actual operation, the first level terminal VD1 may be a low level input terminal, the second level terminal VD2 may be a high level input terminal, the first level may be a low level, and the second level may be a high level. However, the level value of the first level and the level value of the second level may be changed according to the actual situation, which is not limited here.

Upon specific implementation, during the operation of the embodiment of FIG. 1, in an output cutoff holding phase after the reset phase until the input phase of the GOA unit in the next frame, since the reset control terminal Ctrl may employ a second clock signal terminal in actual operation, in the output cutoff holding phase, it is not the gate driving signal reset sub-circuit 13 that is always operating, but the gate driving signal reset sub-circuit 13 resets the gate driving signal only when the second clock signal is at the second level (the second level may be a high level). If, at that time, the gate driving signal output transistor included in the gate driving signal output sub-circuit 12 and/or the gate driving signal reset transistor included in the gate driving signal reset sub-circuit 13 causes an undesirable phenomenon such as current leakage, an incorrect gate driving signal will be outputted in the output cutoff holding phase of the GOA unit from which a valid gate driving signal should not be outputted, resulting in a phenomenon of display failure. In order to solve the above problem, the embodiment of the shift register unit shown in FIG. 2 employs a first pull-down control sub-circuit 14, a pull-down node control sub-circuit 15 and a second pull-down control sub-circuit 16. The pull-down node control sub-circuit 15 can control the potential of the pull-down node PD to be the second level (the second level may be a high level) when the potential of the pull-up node PU is the first level (the first level may be a low level). Further, the first pull-down control sub-circuit 14 and the second pull-down control sub-circuit 16 can ensure that the potential of the pull-up node PU and the potential of the gate driving signal are the first level (the first level may be a low level) in the output cutoff holding phase, thereby eliminating the phenomenon of display failure.

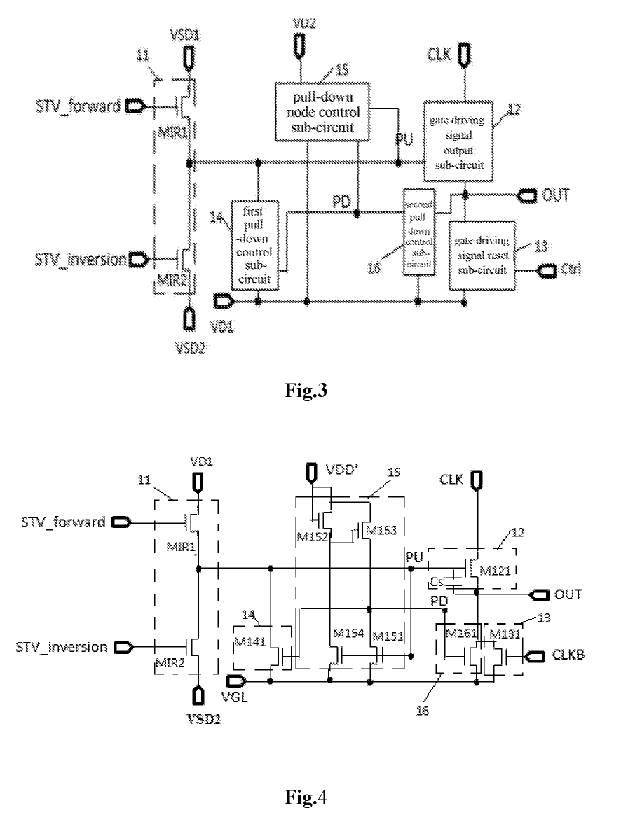

Specifically, as shown in FIG. 3, the input reset sub-circuit 11 comprises a first input reset transistor MIR1 and a second input reset transistor MIR2.

A gate of the first input reset transistor MIR1 is connected to the first scan control terminal STV_forward, a first terminal of the first input reset transistor MIR1 is connected to the first scan level terminal VSD1, and a second terminal of the first input reset transistor MIR1 is connected to the pull-up node PU.

A gate of the second input reset transistor MIR2 is connected to the second scan control terminal STV_inversion, a first terminal of the second input reset transistor MIR2 is connected to the pull-up node PU, and a second terminal of the second input reset transistor MIR2 is connected to the second scan level terminal VSD2.

During forward scanning, the first scan control terminal STV_forward is an input terminal and the second scan control terminal STV_inversion is a reset terminal. During reverse scanning, the first scan control terminal STV_forward is a reset terminal and the second scan control terminal STV_inversion is an input terminal.

As can be seen from FIG. 3, in the shift register unit provided by embodiments of the present disclosure, the first input reset transistor MIR1 and the second input reset transistor MIR2 are symmetrically disposed. During forward scanning, the gate of MIR1 is supplied with an input signal, the gate of MIR2 is supplied with a reset signal, VSD1 inputs a high level, and VSD2 inputs a low level. During reverse scanning, the gate of MIR1 is supplied with a reset signal, the gate of MIR2 is supplied with an input signal, VSD1 inputs a low level, and VSD2 inputs a high level.

Specifically, the gate driving signal output sub-circuit may comprise:

a gate driving signal output transistor, a gate of which is connected to the pull-up node, a first terminal of which is connected to the first clock signal terminal, and a second terminal of which is connected to the gate driving signal output terminal; and,

a storage capacitor, a first terminal of which is connected to the pull-up node, and a second terminal of which is connected to the gate driving signal output terminal.

Specifically, the gate driving signal reset sub-circuit may comprise a gate driving signal reset transistor.

The gate of the gate driving signal reset transistor is the reset control terminal.

The gate of the gate driving signal reset transistor is connected to the second clock signal terminal, a first terminal of the gate driving signal reset transistor is connected to the gate driving signal output terminal, and a second terminal of the gate driving signal reset transistor is connected to the first level terminal.

The first clock signal is opposite in phase to the second clock signal inputted from the second clock signal terminal.

Specifically, the pull-down node control sub-circuit may comprise:

a first pull-down node control transistor, a gate of which is connected to the pull-up node, a first terminal of which is connected to the pull-down node, and a second terminal of which is connected to the first level terminal;

a second pull-down node control transistor, a gate and a first terminal of which are both connected to the second level terminal,

a third pull-down node control transistor, a gate of which is connected to the second terminal of the second pull-down node control transistor, a first terminal of which is connected to the second level terminal, and a second terminal of which is connected to the pull-down node; and

a fourth pull-down node control transistor, a gate of which is connected to the pull-up node, a first terminal of which is connected to the second terminal of the second pull-down node control transistor, and a second terminal of which is connected to the first level terminal.

Specifically, the first pull-down control sub-circuit may comprise a first pull-down control transistor, a gate of which is connected to the pull-down node, a first terminal of which is connected to the pull-up node, and a second terminal of which is connected to the first level terminal.

The second pull-down control sub-circuit comprises a second pull-down control transistor, a gate of which is connected to the pull-down node, a first terminal of which is connected to the gate driving signal output terminal, and a second terminal of which is connected to the first level terminal.

The shift register unit provided by the present disclosure is illustrated below by a specific embodiment.

As shown in FIG. 4, a specific embodiment of the shift register unit provided by the present disclosure comprises an input reset sub-circuit 11, a gate driving signal output sub-circuit 12, a gate driving signal reset sub-circuit 13, a first pull-down control sub-circuit 14, a pull-down node control sub-circuit 15 and a second pull-down control sub-circuit 16.

The input reset sub-circuit 11 comprises a first input reset transistor MIR1 and a second input reset transistor MIR2.

A gate of the first input reset transistor MIR1 is connected to the first scan control terminal STV_forward, a drain of the first input reset transistor MIR1 is connected to the first scan level terminal VSD1, and a source of the first input reset transistor MIR1 is connected to the pull-up node PU.

A gate of the second input reset transistor MIR2 is connected to the second scan control terminal STV_inversion, a drain of the second input reset transistor MIR2 is connected to the pull-up node PU, and a source of the second input reset transistor MIR2 is connected to the second scan level terminal VSD2.

The gate driving signal output sub-circuit 12 comprises:

a gate driving signal output transistor M121, a gate of which is connected to the pull-up node PU, a drain of which is connected to the first clock signal terminal CLK, and a second terminal of which is connected to the gate driving signal output terminal OUT; and,

a storage capacitor Cs, a first terminal of which is connected to the pull-up node PU and a second terminal of which is connected to the gate driving signal output terminal OUT.

The gate driving signal reset sub-circuit 13 comprises a gate driving signal reset transistor M131.

A gate of the gate driving signal reset transistor M131 is connected to a second clock signal terminal CLKB, a drain of the gate driving signal reset transistor M131 is connected to the gate driving signal output terminal OUT, and a source of the gate driving signal reset transistor M131 is connected to a low level terminal VGL.

The first clock signal inputted from CLK and the second clock signal inputted from CLKB are opposite in phase.

The pull-down node control sub-circuit 15 may comprise:

a first pull-down node control transistor M151, a gate of which is connected to the pull-up node PU, a drain of which is connected to the pull-down node PD, and a source of which is connected to the low level terminal VGL;

a second pull-down node control transistor M152, a gate and a drain of which are both connected to a high level terminal VDD′;

a third pull-down node control transistor M153, a gate of which is connected to the source of the second pull-down node control transistor M152, a drain of which is connected to the high level terminal VDD′, and a source of which is connected to the pull-down node PD; and

a fourth pull-down node control transistor M154, a gate of which is connected to the pull-up node PU, a drain of which is connected to the source of the second pull-down node control transistor M152, and a source of which is connected to the low level terminal VGL.

The first pull-down control sub-circuit 14 comprises a first pull-down control transistor M141, a gate of which is connected to the pull-down node PD, a drain of which is connected to the pull-up node PU, and a source of which is connected to the low level terminal VGL.

The second pull-down control sub-circuit 16 comprises a second pull-down control transistor M161, a gate of which is connected to the pull-down node PD, a drain of which is connected to the gate driving signal output terminal, and a source of which is connected to the low level terminal VGL.

In FIG. 4, all the transistors are n-type transistors.

In the embodiment shown in FIG. 4, VDD may be fed with 30V, and VGL may be fed with −8V. However, in actual operation, VDD may also be fed with other high levels, and VGL may also be fed with other low levels.

During forward scanning of the shift register unit shown in FIG. 4, STV_forward is fed with an input signal, STV_inversion is fed with a reset signal, VSD1 is fed with a high level, VSD2 is fed with a low level, STV_forward is connected to a gate driving signal output terminal of a shift register unit of an adjacent previous row, and STV_inversion is connected to a gate driving signal output terminal of a shift register unit of an adjacent next row.

During reverse scanning of the shift register unit shown in FIG. 4, STV_forward is fed with an reset signal, STV_inversion is fed with an input signal, VSD1 is fed with a low level, VSD2 is fed with a high level, STV_forward is connected to a gate driving signal output terminal of a shift register unit of an adjacent next row, and STV_inversion is connected to a gate driving signal output terminal of a shift register unit of an adjacent previous row.

The operation process of the specific embodiment of the shift register unit as shown in FIG. 4 during forward scanning is described below as an example.

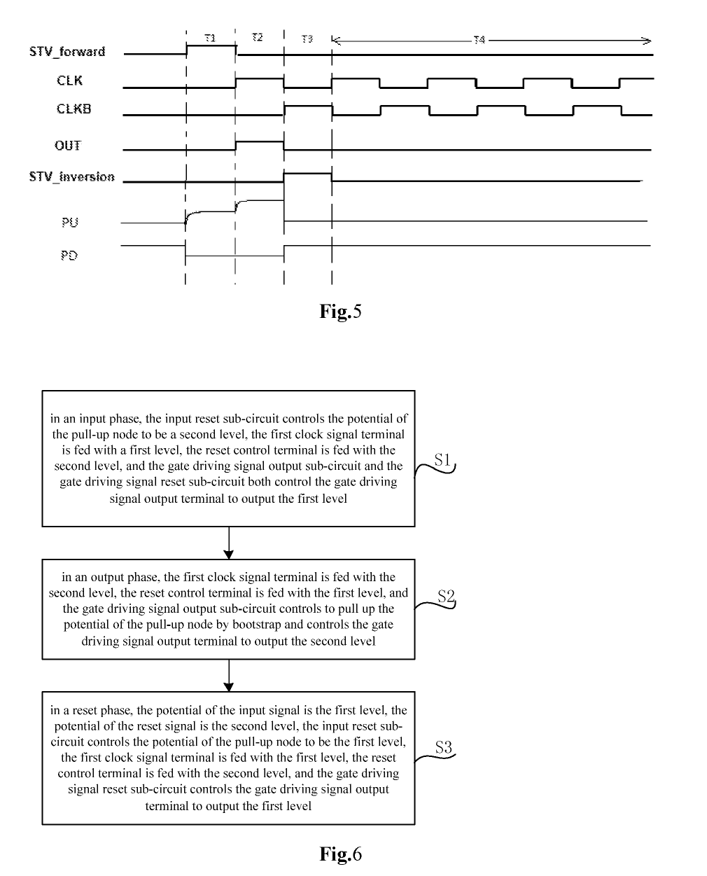

As shown in FIG. 5, in an input phase T1 within each frame, an input signal fed through STV_forward is at a high level, a reset signal fed through STV_inversion is at a low level, CLK is fed with a low level, CLKB is fed with a high level, MIR1 is turned on, MIR2 is turned off, the potential of PU is pulled up to a high level, and M121 and M131 are both turned on so that OUT outputs a low level.

In the input phase T1, since the potential of PU is a high level, M151 and M154 are both turned on so that the potential of PD is pulled down to a low level, the gate potential of M153 is also pulled down to a low level, leading to turn off of M153, and M141 and M161 are turned off.

In an output phase T2 within each frame, the input signal fed through STV_forward is at a low level, the reset signal fed through STV_inversion is at a low level, CLK is fed with a high level, CLKB is fed with a low level, the potential of PU is further pulled up due to the bootstrap effect of Cs, M121 is turned on, and M131 is turned off so that OUT outputs a high level.

In the output phase T2, since the potential of PU continues to be a high level, both M151 and M154 continue to be turned on, so that the potential of PD continues to be pulled down to a low level, the gate potential of M153 also continues to be pulled down to a low level, M153 is turned off, and M141 and M161 continue to be turned off.

In a reset phase T3 within each frame, the input signal fed through STV_forward is at a low level, the reset signal fed through STV_inversion is at a high level (i.e. a gate driving signal outputted by a shift register unit of an adjacent next row is at a high level), CLK is fed with a low level, CLKB is fed with a high level, MIR1 is turned off, MIR2 is turned on, the potential of PU is discharged to a low level, M121 is turned off, and M131 is turned on, so that OUT outputs a low level.

In the reset phase T3, since the potential of PU is a low level, M151 and M154 are both turned off and M152 is turned on so that the gate potential of M153 is a high level to control M153 to be turned on, and the potential of PD is pulled up to a high level so that M141 and M161 are both turned on, further pulling down the potential of PU and the potential of the gate driving signal.

In an output cutoff phase T4 (i.e. after the end of the reset phase T3 within each frame until the start of an input phase of the next frame), the potential of the input signal fed through STV_forward is a low level, the reset signal fed through STV_inversion is at a low level, CLK is fed with a high level and a low level alternately, and CLKB is fed with a low level and a high level alternately. Since the potential of PU is always a low level in the output cutoff phase T4, M151 and M154 are both turned off and M152 is turned on so that the gate potential of M153 is a high level to control M153 to be turned on, and the potential of PD is pulled up to a high level so that M141 and M161 are turned on, further pulling down the potential of PU and the potential of the gate driving signal. Moreover, when CLKB is fed with a high level, M131 is turned on to further control the potential of the gate driving signal to be a low level.

As shown in FIG. 6, embodiments of the present disclosure provide a driving method of a shift register unit for driving the shift register unit described above. The driving method comprises:

S1: in an input phase, the input reset sub-circuit controls the potential of the pull-up node to be a second level, the first clock signal terminal is fed with a first level, the reset control terminal is fed with the second level, and the gate driving signal output sub-circuit and the gate driving signal reset sub-circuit both control the gate driving signal output terminal to output the first level;

S2: in an output phase, the first clock signal terminal is fed with the second level, the reset control terminal is fed with the first level, and the gate driving signal output sub-circuit controls to pull up the potential of the pull-up node by bootstrap and controls the gate driving signal output terminal to output the second level;

S3: in a reset phase, the potential of the input signal is the first level, the potential of the reset signal is the second level, the input reset sub-circuit controls the potential of the pull-up node to be the first level, the first clock signal terminal is fed with the first level, the reset control terminal is fed with the second level, and the gate driving signal reset sub-circuit controls the gate driving signal output terminal to output the first level.

When the driving method of the shift register unit provided by embodiments of the present disclosure is being performed, the structures of the input reset sub-circuit for input and reset are mutually symmetrical during forward scanning and reverse scanning so that the driving method of the shift register unit provided by embodiments of the present disclosure can conveniently realize bidirectional scanning in a GOA driving of a TV (television) product.

Specifically, during forward scanning,

the step in which the input reset sub-circuit controls the potential of the pull-up node to be the second level in the input phase comprises: in the input phase, a potential of an input signal fed through the first scan control terminal being the second level, a potential of a reset signal fed through the second scan control terminal being the first level, the first scan level terminal being fed with the second level, and the input reset sub-circuit controlling the pull-up node to connect with the first scan level terminal so as to control the potential of the pull-up node to be the second level;

the step in which the input reset sub-circuit controls the potential of the pull-up node to the first level in the reset phase comprises: in the reset phase, the potential of the input signal being the first level, the potential of the reset signal being the second level, the second scan level terminal is fed with the first level, and the input reset sub-circuit controlling the pull-up node to connect with the second scan level terminal so as to control the potential of the pull-up node to be the first level.

Specifically, during reverse scanning,

the step in which the input reset sub-circuit controls the potential of the pull-up node to be the second level in the input phase comprises: in the input phase, the potential of the input signal fed through the second scan control terminal being the second level, the potential of the reset signal fed through the first scan control terminal being the first level, the second scan level terminal being fed with the second level, and the input reset sub-circuit controlling the pull-up node to connect with the second scan level terminal so as to control the potential of the pull-up node to be the second level;

the steps in which the potential of the input signal is the first level, the potential of the reset signal is the second level, and the input reset sub-circuit controls the potential of the pull-up node to be the first level in the reset phase comprise: in the reset phase, the potential of the input signal being the first level, the potential of the reset signal being the second level, the first scan level terminal being fed with the first level, and the input reset sub-circuit controlling the pull-up node to connect with the first scan level terminal so as to control the potential of the pull-up node to be the first level.

Specifically, after the reset phase, the driving method of the shift register unit further comprises:

an output cutoff holding phase, in which the reset control terminal is fed with the second level every other clock cycle and the gate driving signal reset sub-circuit controls the gate driving signal output terminal to output the first level.

Specifically, when the shift register unit comprises the first pull-down control sub-circuit, the pull-down node control sub-circuit and the second pull-down control sub-circuit, the driving method further comprises:

in the input phase and the output phase, the pull-down node control sub-circuit controlling the potential of the pull-down node to be the first level;

in the reset phase and the output cutoff holding phase, the pull-down node control sub-circuit controlling the potential of the pull-down node to be the second level, the first pull-down control sub-circuit controlling the potential of the pull-up node to be the first level, and the second pull-down control sub-circuit controlling the gate driving signal output terminal to output the first level.

Embodiments of the present disclosure provide a gate driving circuit comprising multiple rows of the shift register units described above. The first scan control terminal of the shift register unit of each row except the shift register unit of the first row is connected to the gate driving signal output terminal of the shift register unit of an adjacent previous row, and the second scan control terminal of the shift register unit of each row except the shift register unit of the last row is connected to the gate driving signal output terminal of the shift register unit of an adjacent next row.

In the gate driving circuit provided by embodiments of the present disclosure, the row connection manner for the GOA units of respective rows is that the gate driving signal outputted by the GOA unit of a current row is used as an input signal of the GOA unit of a next row, and the gate driving signal outputted by the GOA unit of the current row is used as a reset signal of the GOA unit of a previous row. In order to enable the gate driving circuit to support bidirectional scanning, the gate driving circuit provided by embodiments of the present disclosure requires STV_forward and STV_inversion to be connected in a symmetrical manner, and the row connection manner requires the beginning and the end of the gate driving circuit to be symmetrical.

During forward scanning, STV_forward of the GOA unit of the first row is fed with a frame start scan signal. When the scanning of the GOA unit of the last row finishes, STV_inversion of the GOA unit of the last row is fed with an end pulse (i.e. a frame end reset signal) to reset the GOA unit of the last row. During reverse scanning, STV_inversion of the GOA unit of the last row is fed with a frame start scan signal. When the scanning of the GOA unit of the first row finishes, STV_inversion of the GOA unit of the first row is fed with an end pulse (i.e. a frame end reset signal) to reset the GOA unit of the first row.

In actual operation, during the operation of the gate driving circuit provided by embodiments of the present disclosure, the beginning and the end of GOA both require a row of dummy signal.

During forward scanning, the gate driving signal outputted by the gate driving signal output terminal of the shift register unit of the first row is only used to provide an input signal for the shift register unit of the second row, but not driving a corresponding gate line.

During reverse scanning, the gate driving signal outputted by the gate driving signal output terminal of the shift register unit of the last row is only used to provide an input signal for the shift register unit of an adjacent previous row, but not driving a corresponding gate line.

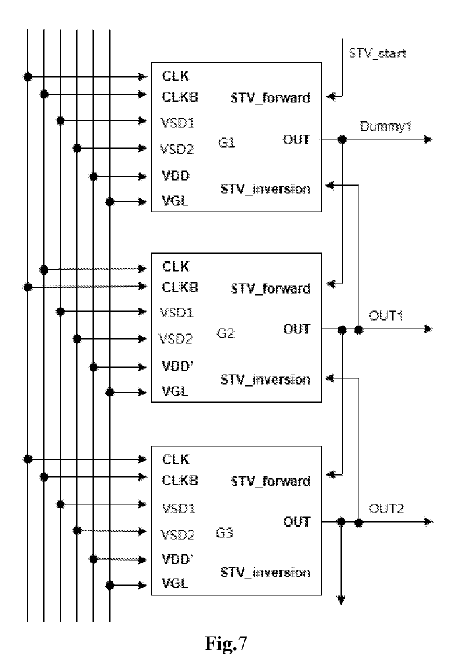

As shown in FIG. 7, during forward scanning, the first scan control terminal STV_forward of a shift register unit G1 of the first row is fed with a frame start scan signal STV_start, VSD1 is fed with a high level, and VSD2 is fed with a low level. STV_inversion of a shift register unit of the last row (not shown in FIG. 7) is fed with a frame end reset signal.

STV_forward of a shift register unit G2 of the second row is connected to OUT of the shift register unit G1 of the first row, and STV_inversion of the shift register unit G2 of the second row is connected to OUT of a shift register unit G3 of the third row.

STV_forward of the shift register unit G3 of the third row is connected to OUT of the shift register unit G2 of the second row.

G1 outputs a dummy signal Dummy 1. G2 outputs a first gate driving scan signal OUT1. G3 outputs a second gate driving scan signal OUT2.

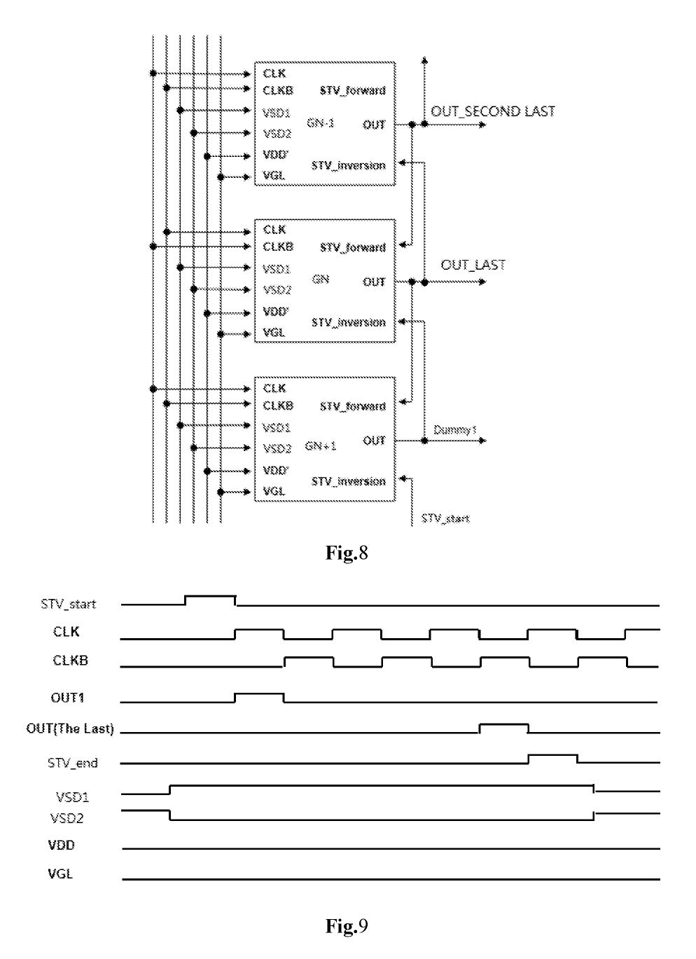

As shown in FIG. 8, during reverse scanning, STV_inversion of a shift register unit GN+1 of the last row is fed with STV_start, VSD1 is fed with a low level, VSD2 is fed with a high level. STV_forward of a shift register unit of the first row (not shown in FIG. 8) is fed with a frame end reset signal. STV_forward of a shift register unit G1 of the last row is connected to OUT of a shift register unit GN of the last but one row.

STV_forward of the shift register unit GN of the last but one row is connected to OUT of a shift register unit GN−1 of the last but two row, and STV_inversion of the shift register unit GN of the last but one row is connected to OUT of the shift register unit GN+1 of the last row.

GN+1 outputs a dummy signal Dummy 1. GN outputs a gate driving signal OUT_LAST of the last row. GN−1 outputs a gate driving signal OUT_SECOND LAST of the last but one row. N is an integer greater than two.

As shown in FIG. 9, VSD1 and VSD2 are alternately high and low to achieve control of forward and reverse scanning.

The frame start scan signal STV_start and the frame end reset signal STV_end may also be interchanged during forward scanning and reverse scanning.

The above is exemplary implementations of the present disclosure. It is to be noted that various improvements and modifications may be further made by those ordinarily skilled in the art without departing from the principle of the present disclosure, and these improvements and modifications should also be considered as falling within the protection scope of the present disclosure.

1. A shift register unit, comprising:
an input reset sub-circuit, wherein the input reset sub-circuit is connected to a first scan control terminal, a second scan control terminal, a first scan level terminal, a second scan level terminal and a pull-up node, respectively, and is configured to control the pull-up node to connect with one of the first scan level terminal and the second scan level terminal under the control of a first scan control signal fed through the first scan control terminal and a second scan control signal fed through the second scan control terminal;
a gate driving signal output sub-circuit, wherein the gate driving signal output sub-circuit is connected to the pull-up node, a gate driving signal output terminal and a first clock signal terminal, respectively, and is configured to control the gate driving signal output terminal to connect with the first clock signal terminal in response to a potential of the pull-up node being a first gating potential; and,
a gate driving signal reset sub-circuit, wherein the gate driving signal reset sub-circuit is connected to a reset control terminal, the gate driving signal output terminal and a first level terminal, respectively, and is configured to control the gate driving signal output terminal to connect with the first level terminal under the control of a reset control signal loaded through the reset control terminal,
wherein during forward scanning, the first scan control terminal acts as an input terminal and the second scan control terminal acts as a reset terminal; during reverse scanning, the first scan control terminal acts as the reset terminal and the second scan control terminal acts as the input terminal.

2. The shift register unit according to claim 1, wherein
the input reset sub-circuit comprises a first input reset transistor and a second input reset transistor;
a gate of the first input reset transistor is connected to the first scan control terminal, a first terminal of the first input reset transistor is connected to the first scan level terminal, and a second terminal of the first input reset transistor is connected to the pull-up node;
a gate of the second input reset transistor is connected to the second scan control terminal, a first terminal of the second input reset transistor is connected to the pull-up node, and a second terminal of the second input reset transistor is connected to the second scan level terminal.

3. The shift register unit according to claim 1, further comprising:
a first pull-down control sub-circuit, wherein the first pull-down control sub-circuit is connected to the pull-up node, a pull-down node and the first level terminal, respectively, and is configured to control the pull-up node to connect with the first level terminal in response to a potential of the pull-down node being a second level;
a pull-down node control sub-circuit, wherein the pull-down node control sub-circuit is connected to the pull-up node, the pull-down node, the second level terminal and the first level terminal, respectively, and is configured to control the pull-down node to connect with the first level terminal in response to the potential of the pull-up node being a second gating potential, and control the pull-down node to connect with the second level terminal in response to the potential of the pull-up node being a first level; and
a second pull-down control sub-circuit, wherein the second pull-down control sub-circuit is connected to the pull-down node, the gate driving signal output terminal and the first level terminal, respectively, and is configured to control the gate driving signal output terminal to connect with the first level terminal in response to the potential of the pull-down node being the second level.

4. The shift register unit according to claim 1, wherein the gate driving signal output sub-circuit comprises:
a gate driving signal output transistor, wherein a gate of the gate driving signal output transistor is connected to the pull-up node, a first terminal of the gate driving signal output transistor is connected to the first clock signal terminal, and a second terminal of the gate driving signal output transistor is connected to the gate driving signal output terminal;
a storage capacitor, wherein a first terminal of the storage capacitor is connected to the pull-up node, and a second terminal of the storage capacitor is connected to the gate driving signal output terminal.

5. The shift register unit according to claim 4, wherein the gate driving signal reset sub-circuit comprises a gate driving signal reset transistor, wherein
a gate of the gate driving signal reset transistor acts as the reset control terminal;
the gate of the gate driving signal reset transistor is connected to a second clock signal terminal, a first terminal of the gate driving signal reset transistor is connected to the gate driving signal output terminal, and a second terminal of the gate driving signal reset transistor is connected to the first level terminal; and
the first clock signal and a second clock signal fed through the second clock signal terminal are opposite in phase.

6. The shift register unit according to claim 2, wherein the pull-down node control sub-circuit comprises:
a first pull-down node control transistor, wherein a gate of the first pull-down node control transistor is connected to the pull-up node, a first terminal of the first pull-down node control transistor is connected to the pull-down node, and a second terminal of the first pull-down node control transistor is connected to the first level terminal;
a second pull-down node control transistor, wherein a gate and a first terminal of the second pull-down node control transistor are both connected to a second level terminal,
a third pull-down node control transistor, wherein a gate of the third pull-down node control transistor is connected to a second terminal of the second pull-down node control transistor, a first terminal of the third pull-down node control transistor is connected to the second level terminal, and a second terminal of the third pull-down node control transistor is connected to the pull-down node; and
a fourth pull-down node control transistor, wherein a gate of the fourth pull-down node control transistor is connected to the pull-up node, a first terminal of the fourth pull-down node control transistor is connected to the second terminal of the second pull-down node control transistor, and a second terminal of the fourth pull-down node control transistor is connected to the first level terminal.

7. The shift register unit according to claim 2, wherein the first pull-down sub-circuit comprises a first pull-down control transistor, wherein a gate of the first pull-down control transistor is connected to the pull-down node, a first terminal of the first pull-down control transistor is connected to the pull-up node, and a second terminal of the first pull-down control transistor is connected to the first level terminal;
the second pull-down control sub-circuit comprises a second pull-down control transistor, wherein a gate of the second pull-down control transistor is connected to the pull-down node, a first terminal of the second pull-down control transistor is connected to the gate driving signal output terminal, and a second terminal of the second pull-down control transistor is connected to the first level terminal.

8. A driving method of a shift register unit for driving the shift register unit according to claim 1, wherein the driving method comprises:
in an input phase, the input reset sub-circuit controlling the potential of the pull-up node to be a second level, the first clock signal terminal being fed with a first level, the reset control terminal being fed with the second level, both the gate driving signal output sub-circuit and the gate driving signal reset sub-circuit controlling the gate driving signal output terminal to output the first level;
in an output phase, the first clock signal terminal being fed with the second level, the reset control terminal being fed with the first level, the gate driving signal output sub-circuit controlling to pull up the potential of the pull-up node by bootstrap and controlling the gate driving signal output terminal to output the second level;
in a reset phase, a potential of an input signal being the first level, a potential of a reset signal being the second level, the input reset sub-circuit controlling the potential of the pull-up node to be the first level, the first clock signal terminal being fed with the first level, the reset control terminal being fed with the second level, the gate driving signal reset sub-circuit controlling the gate driving signal output terminal to output the first level.

9. The driving method of a shift register unit according to claim 8, wherein during forward scanning,
the step of in an input phase, the input reset sub-circuit controlling the potential of the pull-up node to be the second level comprises: in the input phase, a potential of an input signal fed through the first scan control terminal being the second level, a potential of a reset signal fed through the second scan control terminal being the first level, the first scan level terminal being fed with the second level, the input reset sub-circuit controlling the pull-up node to connect with the first scan level terminal so as to control the potential of the pull-up node to be the second level;
the step of in a reset phase, the input reset sub-circuit controlling the potential of the pull-up node to be the first level comprises: in the reset phase, the potential of the input signal being the first level, the potential of the reset signal being the second level, the second scan level terminal being fed with the first level, the input reset sub-circuit controlling the pull-up node to connect with the second scan level terminal so as to control the potential of the pull-up node to be the first level.

10. The driving method of a shift register unit according to claim 8, wherein during reverse scanning,
the step of in an input phase, the input reset sub-circuit controlling the potential of the pull-up node to be the second level comprises: in the input phase, a potential of an input signal fed through the second scan control terminal being the second level, a potential of a reset signal fed through the first scan control terminal being the first level, the second scan level terminal being fed with the second level, the input reset sub-circuit controlling the pull-up node to connect with the second scan level terminal so as to control the potential of the pull-up node to be the second level;
the step of in a reset phase, a potential of an input signal being the first level, a potential of a reset signal being the second level, the input reset sub-circuit controlling the potential of the pull-up node to be the first level comprise: in the reset phase, the potential of the input signal being the first level, the potential of the reset signal being the second level, the first scan level terminal being fed with the first level, the input reset sub-circuit controlling the pull-up node to connect with the first scan level terminal so as to control the potential of the pull-up node to be the first level.

11. The driving method of a shift register unit according to claim 8, after the reset phase, further comprising:
an output cutoff holding phase, in which the reset control terminal is fed with the second level every other clock cycle, and in response to the reset control terminal outputting the second level, the gate driving signal reset sub-circuit controls the gate driving signal output terminal to output the first level.

12. The driving method of a shift register unit according to claim 11, wherein
the shift register unit further comprises; and
the driving method further comprises:
in the input phase and the output phase, the pull-down node control sub-circuit controlling the potential of the pull-down node to be the first level;
in the reset phase and the output cutoff holding phase, the pull-down node control sub-circuit controlling the potential of the pull-down node to be the second level, the first pull-down control sub-circuit controlling the potential of the pull-up node to be the first level, the second pull-down control sub-circuit controlling the gate driving signal output terminal to output the first level.

13. A gate driving circuit comprising multiple rows of the shift register units according to claim 1, wherein
a first scan control terminal of a shift register unit of each row except a shift register unit of the first row is connected to a gate driving signal output terminal of a shift register unit of an adjacent previous row, and a second scan control terminal of a shift register unit of each row except a shift register unit of the last row is connected to a gate driving signal output terminal of a shift register unit of an adjacent next row.

14. The shift register unit according to claim 2, further comprising:
a first pull-down control sub-circuit, wherein the first pull-down control sub-circuit is connected to the pull-up node, a pull-down node and the first level terminal, respectively, and is configured to control the pull-up node to connect with the first level terminal in response to a potential of the pull-down node being a second level;
a pull-down node control sub-circuit, wherein the pull-down node control sub-circuit is connected to the pull-up node, the pull-down node, the second level terminal and the first level terminal, respectively, and is configured to control the pull-down node to connect with the first level terminal in response to the potential of the pull-up node being a second gating potential, and control the pull-down node to connect with the second level terminal in response to the potential of the pull-up node being a first level; and
a second pull-down control sub-circuit, wherein the second pull-down control sub-circuit is connected to the pull-down node, the gate driving signal output terminal and the first level terminal, respectively, and is configured to control the gate driving signal output terminal to connect with the first level terminal in response to the potential of the pull-down node being the second level.

15. The shift register unit according to claim 2, wherein the gate driving signal output sub-circuit comprises:
a gate driving signal output transistor, wherein a gate of the gate driving signal output transistor is connected to the pull-up node, a first terminal of the gate driving signal output transistor is connected to the first clock signal terminal, and a second terminal of the gate driving signal output transistor is connected to the gate driving signal output terminal;
a storage capacitor, wherein a first terminal of the storage capacitor is connected to the pull-up node, and a second terminal of the storage capacitor is connected to the gate driving signal output terminal.

16. The driving method of a shift register unit according to claim 8, wherein
the input reset sub-circuit comprises a first input reset transistor and a second input reset transistor;
a gate of the first input reset transistor is connected to the first scan control terminal, a first terminal of the first input reset transistor is connected to the first scan level terminal, and a second terminal of the first input reset transistor is connected to the pull-up node;
a gate of the second input reset transistor is connected to the second scan control terminal, a first terminal of the second input reset transistor is connected to the pull-up node, and a second terminal of the second input reset transistor is connected to the second scan level terminal.

17. The driving method of a shift register unit according to claim 8, wherein the shift register unit further comprises:
a first pull-down control sub-circuit, wherein the first pull-down control sub-circuit is connected to the pull-up node, a pull-down node and the first level terminal, respectively, and is configured to control the pull-up node to connect with the first level terminal in response to a potential of the pull-down node being a second level;
a pull-down node control sub-circuit, wherein the pull-down node control sub-circuit is connected to the pull-up node, the pull-down node, the second level terminal and the first level terminal, respectively, and is configured to control the pull-down node to connect with the first level terminal in response to the potential of the pull-up node being a second gating potential, and control the pull-down node to connect with the second level terminal in response to the potential of the pull-up node being a first level; and
a second pull-down control sub-circuit, wherein the second pull-down control sub-circuit is connected to the pull-down node, the gate driving signal output terminal and the first level terminal, respectively, and is configured to control the gate driving signal output terminal to connect with the first level terminal in response to the potential of the pull-down node being the second level.

18. The driving method of a shift register unit according to claim 8, wherein the gate driving signal output sub-circuit comprises:
a gate driving signal output transistor, wherein a gate of the gate driving signal output transistor is connected to the pull-up node, a first terminal of the gate driving signal output transistor is connected to the first clock signal terminal, and a second terminal of the gate driving signal output transistor is connected to the gate driving signal output terminal;
a storage capacitor, wherein a first terminal of the storage capacitor is connected to the pull-up node, and a second terminal of the storage capacitor is connected to the gate driving signal output terminal.

19. The driving method of a shift register unit according to claim 18, wherein the gate driving signal reset sub-circuit comprises a gate driving signal reset transistor, wherein
a gate of the gate driving signal reset transistor acts as the reset control terminal;
the gate of the gate driving signal reset transistor is connected to a second clock signal terminal, a first terminal of the gate driving signal reset transistor is connected to the gate driving signal output terminal, and a second terminal of the gate driving signal reset transistor is connected to the first level terminal; and
the first clock signal and a second clock signal fed through the second clock signal terminal are opposite in phase.

20. The driving method of a shift register unit according to claim 16, wherein the pull-down node control sub-circuit comprises:
a first pull-down node control transistor, wherein a gate of the first pull-down node control transistor is connected to the pull-up node, a first terminal of the first pull-down node control transistor is connected to the pull-down node, and a second terminal of the first pull-down node control transistor is connected to the first level terminal;
a second pull-down node control transistor, wherein a gate and a first terminal of the second pull-down node control transistor are both connected to a second level terminal,
a third pull-down node control transistor, wherein a gate of the third pull-down node control transistor is connected to a second terminal of the second pull-down node control transistor, a first terminal of the third pull-down node control transistor is connected to the second level terminal, and a second terminal of the third pull-down node control transistor is connected to the pull-down node; and
a fourth pull-down node control transistor, wherein a gate of the fourth pull-down node control transistor is connected to the pull-up node, a first terminal of the fourth pull-down node control transistor is connected to the second terminal of the second pull-down node control transistor, and a second terminal of the fourth pull-down node control transistor is connected to the first level terminal.
